(19) United States
(12) Patent Application Publication
(10) Pub. No.: US 2025/0133944 A1
(43) Pub. Date: Apr. 24, 2025

(54) WINDOW AND DISPLAY DEVICE INCLUDING THE SAME

(71) Applicant: Samsung Display Co., LTD., Yongin-si (KR)

(72) Inventors: SUNGWOO KIM, Yongin-si (KR); JONGSEOK JOO, Yongin-si (KR); JAEHONG KIM, Yongin-si (KR)

(21) Appl. No.: 18/786,494

(22) Filed: Jul. 27, 2024

(30) Foreign Application Priority Data
Oct. 18, 2023 (KR) 10-2023-0139415

(51) Int. Cl. H10K 59/80

(52) U.S. Cl. CPC H10K 59/8792; H10K 59/873

(57) ABSTRACT

A window includes a base layer and an anti-reflection layer disposed on the base layer. The anti-reflection layer includes a first layer including a first material and having a first thickness, a second layer including a second material and having a second thickness, and a third layer including the first material and having a third thickness. The first material includes silicon (Si), aluminum (Al), and nitrogen (N) atoms, and the second material includes a silicon oxide. Each of the first thickness and the second thickness ranges from about 10 nm to about 50 nm, and the third thickness ranges from about 400 nm to about 500 nm.

This application claims priority to Korean Patent Application No. 10-2023-0139415, filed on Oct. 18, 2023, and all the benefits accruing therefrom under 35 U.S.C. § 119, the content of which in its entirety is herein incorporated by reference.

### BACKGROUND

The present disclosure herein relates to a window and a display device including the window, and more particularly, to a window having low reflectance and also excellent mechanical characteristics, and a display device including the window.

Display devices are used for various multimedia devices such as, for example, televisions, mobile phones, tablet computers, and game consoles, to provide users with image information. Recently, flexible display devices having various shapes and which are capable of being folded or bent have been developed. The flexible display devices may be variously changed in shape, for example, folded, rolled, or bent, and thus have characteristics supportive of device portability.

Some flexible display devices may include foldable or bendable display panels and windows. However, the windows of the flexible display devices may be deformed due to folding or bending operations or may be easily damaged due to external impacts.

### SUMMARY

The present disclosure provides a window having low reflectance and excellent mechanical characteristics.

The present disclosure also provides a display device with reflectance maintained to be low and with improved durability and reliability.

An embodiment supported by aspects of the present disclosure provides a window including a base layer, and an anti-reflection layer disposed on the base layer. The anti-reflection layer includes a first layer including a first material and having a first thickness, a second layer including a second material and having a second thickness, and a third layer including the first material and having a third thickness. The first material includes silicon (Si), aluminum (Al), and nitrogen (N) atoms, and the second material includes a silicon oxide. Each of the first thickness and the second thickness ranges from about 10 nm to about 50 nm, and the third thickness ranges from about 400 nm to about 500 nm.

In an embodiment, each of the first layer and the third layer may have a refractive index ranging from about 1.7 to about 2.5, and the second layer may have a refractive index ranging from about 1.3 to about 1.7.

In an embodiment, the first layer may be disposed directly on the base layer, the second layer may be disposed directly on the first layer, and the third layer may be disposed directly on the second layer.

In an embodiment, the anti-reflection layer may further include a fourth layer disposed directly on the third layer and including the second material, and the fourth layer may have a refractive index ranging from about 1.4 to about 1.6.

In an embodiment, the fourth layer may have a fourth thickness ranging from about 5 nm to about 15 nm.

In an embodiment, the anti-reflection layer may further include a fifth layer disposed directly on the fourth layer and including the first material, and a sixth layer disposed directly on the fifth layer and including the second material. The fifth layer may have a refractive index of about 1.9 to about 2.5, and the sixth layer may have a refractive index ranging from about 1.4 to about 1.6.

In an embodiment, the fifth layer may have a fifth thickness ranging from about 100 nm to about 200 nm, and the sixth layer may have a sixth thickness ranging from about 40 nm to about 100 nm.

In an embodiment, the sixth layer may include a planarization layer disposed on the fifth layer, and a columnar layer disposed on the planarization layer. A plurality of uneven portions may be provided on a top surface of the columnar layer, and a surface roughness of the top surface of the columnar layer may be greater than a surface roughness of a top surface of the planarization layer.

In an embodiment, the planarization layer may have a refractive index ranging from about 1.4 to about 1.6, and the columnar layer may have a refractive index ranging from about 1.3 to about 1.5.

In an embodiment, the planarization layer may have a thickness of about 20 nm or less, and the columnar layer may have a thickness ranging from about 50 nm to about 100 nm.

In an embodiment, an atomic percent of silicon in the first material may range from about 5 at % to about 20 at %.

In an embodiment, the first material may include a metal nanocomposite including aluminum, silicon, and nitrogen atoms.

In an embodiment, the first material may include an aluminum silicon oxynitride.

In an embodiment, an atomic percent of oxygen in the first material may be about 20 at % or less.

In an embodiment, each of the first layer and the third layer may be a single layer including the first material, and the second layer may be a single layer including the second material.

In an embodiment, the anti-reflection layer may have a hardness of about 20 GPa or greater at an indentation depth of about 100 nm.

In an embodiment, the anti-reflection layer may have stress of about 2 GPa or less at a temperature of about 28° C.

In an embodiment, the window may further include an anti-fingerprint layer disposed on the anti-reflection layer.

In an embodiment supported by aspects of the present disclosure, a display device includes a display module, and a window disposed on the display module and including an anti-reflection layer. The anti-reflection layer includes a first layer including a first material and having a refractive index ranging from about 1.7 to about 2.5, a second layer including a second material and having a refractive index ranging from about 1.3 to about 1.7, and a third layer including the first material and having a refractive index ranging from about 1.7 to about 2.5. The first material includes silicon (Si), aluminum (Al), and nitrogen (N) atoms, the second material includes a silicon oxide, and the third layer has a thickness of about 400 nm to about 500 nm.

In an embodiment, a ratio of the thickness of the first layer to the thickness of the third layer may be about 0.1 or less, and a ratio of the thickness of the second layer to the thickness of the third layer may be about 0.1 or less.

### BRIEF DESCRIPTION OF THE FIGURES

The accompanying drawings are included to provide a further understanding of embodiments supported by aspects of the present disclosure, and are incorporated in and constitute a part of this specification. The drawings illustrate embodiments supported by aspects of the present disclosure and, together with the description, serve to explain principles supported by aspects of the present disclosure. In the drawings:

FIG. 1A is an assembled perspective view of a display device according to an embodiment supported by aspects of the present disclosure;

FIG. 1B is an exploded perspective view of a display device according to an embodiment supported by aspects of the present disclosure;

FIG. 2 is a cross-sectional view of a display device according to an embodiment supported by aspects of the present disclosure;

FIG. 3 is a cross-sectional view illustrating a portion of a display module according to an embodiment supported by aspects of the present disclosure; and

FIGS. 4A to 4D are cross-sectional views of a window according to an embodiment supported by aspects of the present disclosure.

### DETAILED DESCRIPTION

In this specification, it will be understood that when an element (or region, layer, section, or the like) is referred to as being “on,” “connected to” or “coupled to” another element, the element (or region, layer, section, or the like) can be disposed directly on, connected or coupled to the other element or a third element may be disposed between the elements.

Like reference numbers or symbols refer to like elements throughout. In some aspects, in the drawings, the thickness, the ratio, and the dimension of elements are exaggerated for effective description of the technical contents. The term “and/or” includes one or more combinations which may be defined by relevant elements.

It will be understood that, although the terms first, second, and the like may be used herein to describe various elements, these elements should not be limited by these terms. These terms are used to distinguish one element from another element. For example, a first element could be termed a second element without departing from the teachings of the present invention, and similarly, a second element could be termed a first element. As used herein, the singular forms are intended to include the plural forms as well, unless the context clearly indicates otherwise.

In some aspects, the terms, such as, for example, “below,” “beneath,” “on” and “above,” are used for explaining the relation of elements illustrated in the drawings. The terms are relative concept and are explained based on the direction illustrated in the drawing.

It will be further understood that the terms such as, for example, “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments supported by aspects of the present disclosure will be described with reference to the accompanying drawings.

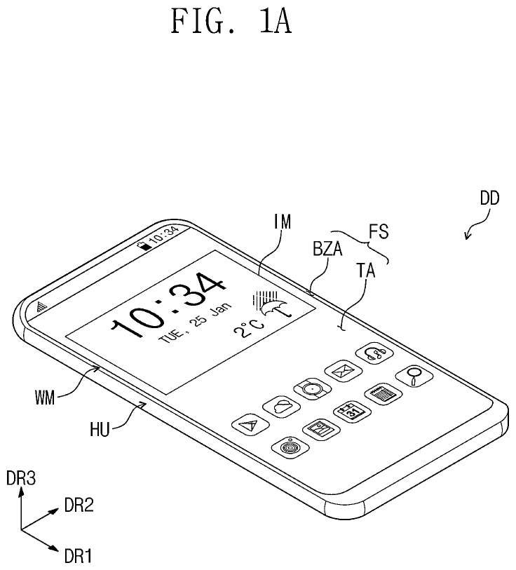

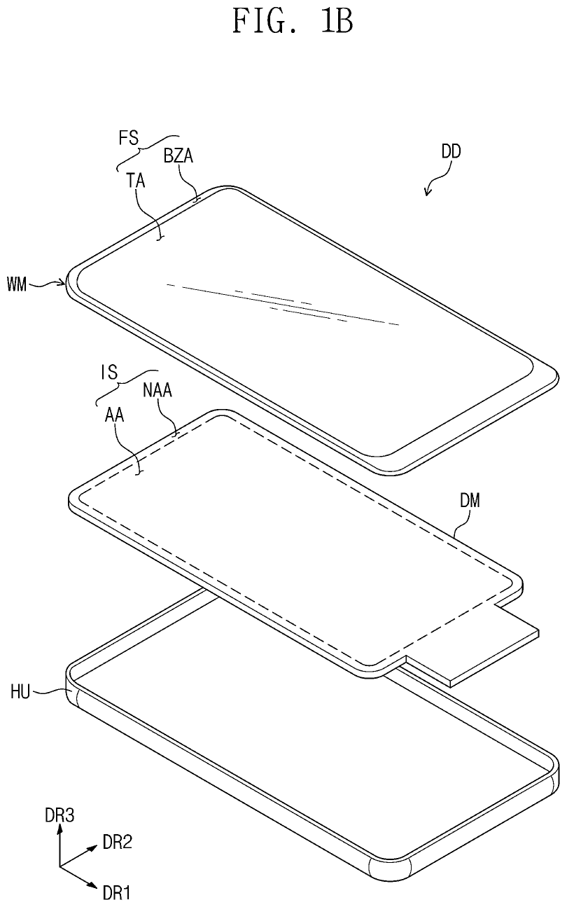

FIG. 1A is an assembled perspective view of a display device according to an embodiment supported by aspects of the present disclosure. FIG. 1B is an exploded perspective view of a display device according to an embodiment supported by aspects of the present disclosure.

Referring to FIGS. 1A and 1B, the display device DD may be a device that is activated in response to an electrical signal. The display device DD may display an image IM and detect an external input. The display device DD may include various embodiments. For example, the display device DD may include a tablet computer, a notebook computer, a computer, a smart television, and the like. In the example embodiment described with reference to FIGS. 1A and 1B, the display device DD is a smartphone, but is not limited thereto.

The display device DD may display the image IM on a display surface FS, which is parallel to each of a first direction DR1 and a second direction DR2, in a third direction DR3. The display surface FS on which the image IM is displayed may correspond to a front surface of the display device DD, and the display surface FS may correspond to a front surface FS of a window WM. Hereinafter, the display surface FS and the front surface of the display device DD and the front surface FS of the window WM are designated by the same reference symbol. The image IM may include a dynamic image and also a still image. FIG. 1A illustrates a clock and a plurality of icons as an example of the image IM.

In this embodiment, a front surface (or top surface) and a rear surface (or bottom surface) of each of members of the display device DD are defined based on a direction in which the image IM is displayed. The front surface and the rear surface may oppose each other in the third direction DR3, and a normal direction to each of the front surface and the rear surface may be parallel to the third direction DR3. A spaced distance between the front surface and the rear surface in the third direction DR3 may correspond to a thickness of a display panel 100 in the third direction DR3.

In some embodiments, directions indicated by the first to third directions DR1, DR2 and DR3 are relative concepts and may be changed to other directions. Hereinafter, the first to third directions are directions indicated by the first to third directions DR1, DR2 and DR3 and designated by the same reference symbols, respectively. In some aspects, the phrase “on a plane” used herein may mean being when viewed in the third direction DR3.

The display device DD according to an embodiment supported by aspects of the present disclosure may detect a user's external input applied from the outside. The user's input includes various types of external inputs such as, for example, part of the user's body, light, heat, or pressure. The user's input may be provided according to various types, and the display device DD may also detect the user's input applied to a side surface or a rear surface of the display device DD based on a structure of the display device DD. However, aspects of the present disclosure are not limited to any one embodiment.

As illustrated in FIG. 1B, the display device DD includes the window WM, a display module DM, and an outer case HU. In this embodiment, the window WM and the outer case HU are coupled to provide an outer appearance of the display device DD. In this embodiment, the outer case HU, the display module DM, and the window WM may be stacked in sequence in the third direction DR3.

The window WM may include an optically transparent material. The window WM may include an insulation panel. For example, the window WM may include glass, plastic, or a combination thereof.

As described herein, the front surface FS of the window WM defines the front surface of the display device DD. A transmission area TA of the window WM may be an optically transparent area. For example, the transmission area TA may be an area having a visible light transmittance of about 90% or greater.

A bezel area BZA of the display device DD may be an area having a relatively low light transmittance compared to the transmission area TA. The bezel area BZA defines a shape of the transmission area TA. The bezel area BZA may be adjacent to the transmission area TA and surround the transmission area TA.

The bezel area BZA may have a predetermined color. The bezel area BZA may cover a peripheral area NAA of the display module DM and prevent the peripheral area NAA from being visible to the outside. However, this is illustrated as one example, and the bezel area BZA may be omitted in the window WM according to an embodiment supported by aspects of the present disclosure.

The display device DD may display the image IM and detect an external input. The image IM may be displayed on a front surface IS of the display module DM. The front surface IS of the display module DM includes an active area AA and a peripheral area NAA. The active area AA may be an area that is activated in response to an electrical signal.

In this embodiment, the active area AA may be an area on which the image IM is displayed, and also an area through which the external input is detected. The transmission area TA at least overlaps the active area AA. For example, the transmission area TA overlaps a front surface or at least a portion of the active area AA. Accordingly, a user may see the image IM or provide an external input through the transmission area TA. However, this is illustrated as an example. For example, in the active area AA, an area on which the image IM is displayed, and an area through which the external input is detected may be separated from each other, and an embodiment supported by aspects of the present disclosure is not limited to any one embodiment.

The peripheral area NAA may be an area that is covered by the bezel area BZA. The peripheral area NAA is adjacent to the active area AA. The peripheral area NAA may surround the active area AA. A driving circuit, driving line, or the like for driving the active area AA may be disposed in the peripheral area NAA.

The display module DM may include a display panel and a sensor layer. The image IM may be displayed substantially on the display panel, and an external pressure may be detected substantially through the sensor layer. The display module DM may display the image IM and also detect the external input by including both the display panel and the sensor layer. This will be described in detail later.

The display device DD according to an embodiment may further include the driving circuit. The driving circuit may include a flexible circuit board and a main circuit board. The flexible circuit board may be electrically connected to the display module DM. The flexible circuit board may connect the display module DM to the main circuit board. However, this is illustrated as an example. For example, the flexible circuit board according to an embodiment supported by aspects of the present disclosure may not be connected to the main circuit board, and the flexible circuit board may be a rigid board.

The flexible circuit board may be connected to pads of the display module DM, which are disposed on the peripheral area NAA. The flexible circuit board may provide the display module DM with an electrical signal for driving the display module DM. The electrical signal may be generated in the flexible circuit board, or generated in the main circuit board. The main circuit board may include various driving circuits for driving the display module DM, a connector for supplying power, or the like. The main circuit board may be connected to the display module DM through the flexible circuit board.

Although FIG. 1B illustrates an example state in which the display module DM is spread out (e.g., unfolded, not bent), at least a portion of the display module DM may be bent. For example, a portion of the display module DM may be bent toward a rear surface of the display module DM, and the portion bent toward the rear surface may be a portion to which the main circuit board is connected. Accordingly, the main circuit board may be assembled in a state in which the main circuit board overlaps the rear surface of the display module DM.

The outer case HU is coupled to the window HU and defines the outer appearance of the display device DD. The outer case HU provides a predetermined inner space. The display module DM may be accommodated in the inner space.

The outer case HU may include a material having relatively high rigidity. For example, the outer case HU may include glass, plastic, or metal, or include a plurality of frames and/or plates formed of a combination thereof. The outer case HU may stably protect components of the display device DD accommodated in the inner space from an external impact.

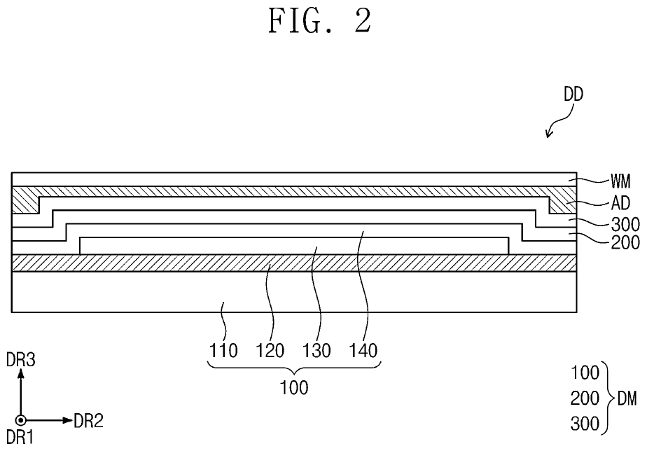

FIG. 2 is a cross-sectional view of a display device according to an embodiment supported by aspects of the present disclosure.

Referring to FIG. 2, the display device DD may include a display module DM and a window WM. The display module DM and the window WM may be coupled to each other through an adhesive layer AD. In the display device DD according to an embodiment, the display module DM may include a display panel 100, a sensor layer 200, and an optical layer 300. The optical layer 300 of a plurality of layers of the display module DM may be coupled to the window WM through the adhesive layer AD.

The display panel 100 may be a component that substantially generates an image. The display panel 100 may be a light emitting display panel. For example, the display panel 100 may be an organic light emitting display panel, an inorganic light emitting display panel, a micro LED display panel, or a nano LED display panel. The display panel 100 may be referred to as a display layer.

The display panel 100 may include a base substrate 110, a circuit layer 120, a light emitting element layer 130, and an encapsulation layer 140.

The base substrate 110 may be a member that provides a base surface on which the circuit layer 120 is disposed. The base substrate 110 may be a rigid substrate, or a flexible substrate that is capable of being bent, folded, rolled, or the like. The base substrate 110 may be a glass substrate, a metal substrate, a polymer substrate, or the like. However, embodiments of the present disclosure are not limited thereto, and the base substrate 110 may be an inorganic layer, an organic layer, or a composite material layer.

The base substrate 110 may have a multilayer structure. For example, the base substrate 110 may include a first synthetic resin layer, a multi-layered or single-layered inorganic layer, and a second synthetic resin layer disposed on the multi-layered or single-layered inorganic layer. Each of the first and second synthetic resin layers may include a polyimide-based resin and is not particularly limited.

The circuit layer 120 may be disposed on the base substrate 110. The circuit layer 120 may include an insulation layer, a semiconductor pattern, a conductive pattern, a signal line, and the like.

The light emitting element layer 130 may be disposed on the circuit layer 120. The light emitting element layer 130 may include a light emitting element. For example, the light emitting element may include an organic light emitting material, an inorganic light emitting material, an organic-inorganic light emitting material, a quantum dot, a quantum rod, a micro LED, or a nano LED.

The encapsulation layer 140 may be disposed on the light emitting element layer 130. The encapsulation layer 140 may protect the light emitting element layer 130 from moisture, oxygen, and foreign matter such as, for example, dust particles. The encapsulation layer 140 may include at least one inorganic layer. The encapsulation layer 140 may include a stacked structure of inorganic layer/organic layer/inorganic layer.

The sensor layer 200 may be disposed on the display panel 100. The sensor layer 200 may detect an external input applied from the outside. The external input may be a user's input. The user's input may include various types of external inputs such as, for example, part of the user's body, light, heat, pen, or pressure.

The sensor layer 200 may be formed on the display panel 100 through a continuous process. In this case, the sensor layer 200 may be disposed directly on the display panel 100. Here, the phrase “being disposed directly” may mean that a third component is not disposed between the sensor layer 200 and the display panel 100. That is, in the example in which the sensor layer 200 is disposed directly on the display panel 100, a separate adhesive member may not be disposed between the sensor layer 200 and the display panel 100.

The optical layer 300 may be disposed directly on the sensor layer 200. The optical layer 300 may reduce reflectance of external light incident the display device DD from the outside of the display device DD. The optical layer 300 may be formed on the sensor layer 200 through a continuous process. The optical layer 300 may include color filters. The color filters may have a predetermined arrangement. For example, the color filters may be arranged based on the color of light emitted by pixels included in the display panel 100. In some aspects, the optical layer 300 may further include a black matrix adjacent to the color filters. The optical layer 300 will be specifically described later.

In an embodiment supported by aspects of the present disclosure, the sensor layer 200 may be omitted. In this case, the optical layer 300 may be disposed directly on the display panel 100. In an embodiment supported by aspects of the present disclosure, the sensor layer 200 and the optical layer 300 may be exchanged with each other.

Although not illustrated, in an embodiment supported by aspects of the present disclosure, the display device DD may further include a functional layer disposed on the optical layer 300. For example, the functional layer may control a direction of light incident the optical layer 300 from the display panel 100 in association with improving front luminance of the display device DD.

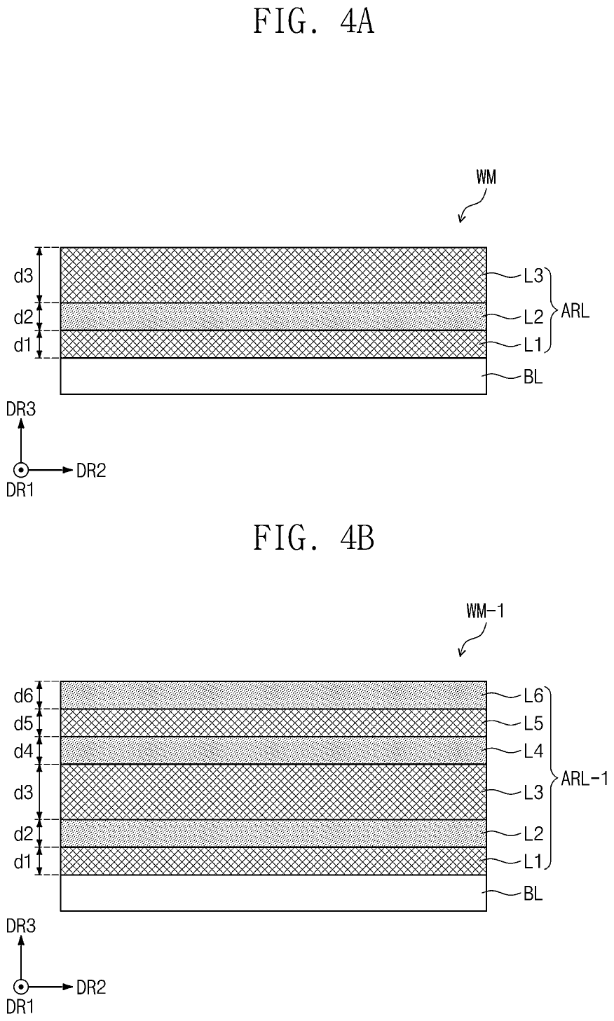

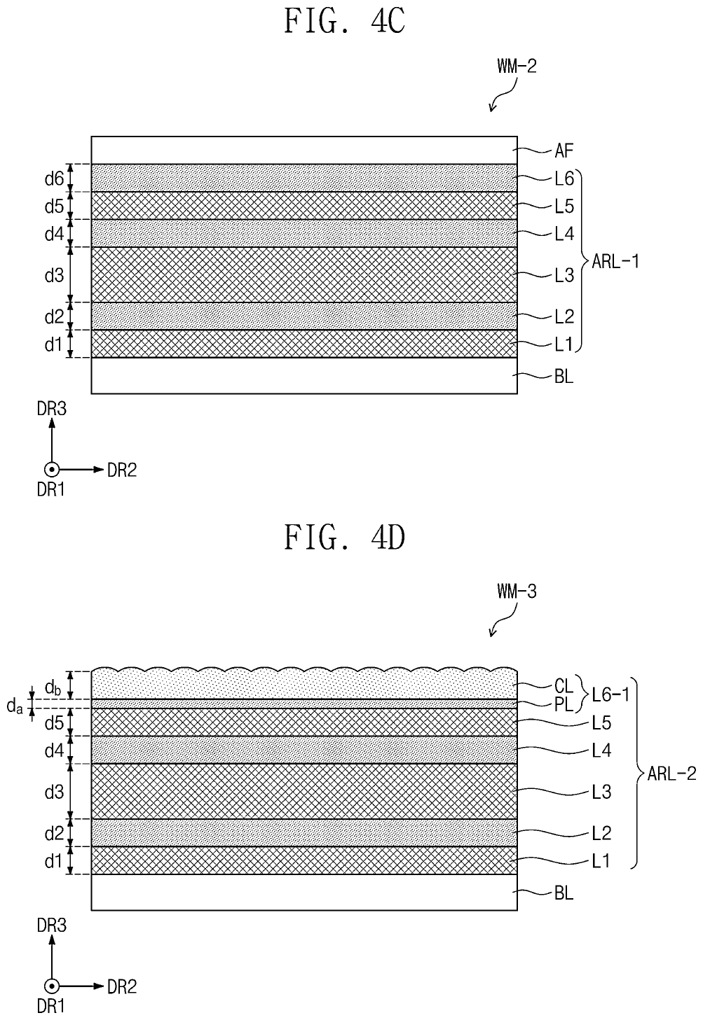

The window WM may provide a front surface of the display device DD. The window WM may include a glass film or synthetic resin film as a base film. The window WM may further include functional layers such as, for example, an anti-reflection layer, an anti-fingerprint layer, or the like. The functional layers included in the window WM will be described in more detail with reference to FIGS. 4A and 4B. Although not illustrated, the window WM may further include a bezel pattern overlapping the bezel area BZA (see FIG. 1B) described herein.

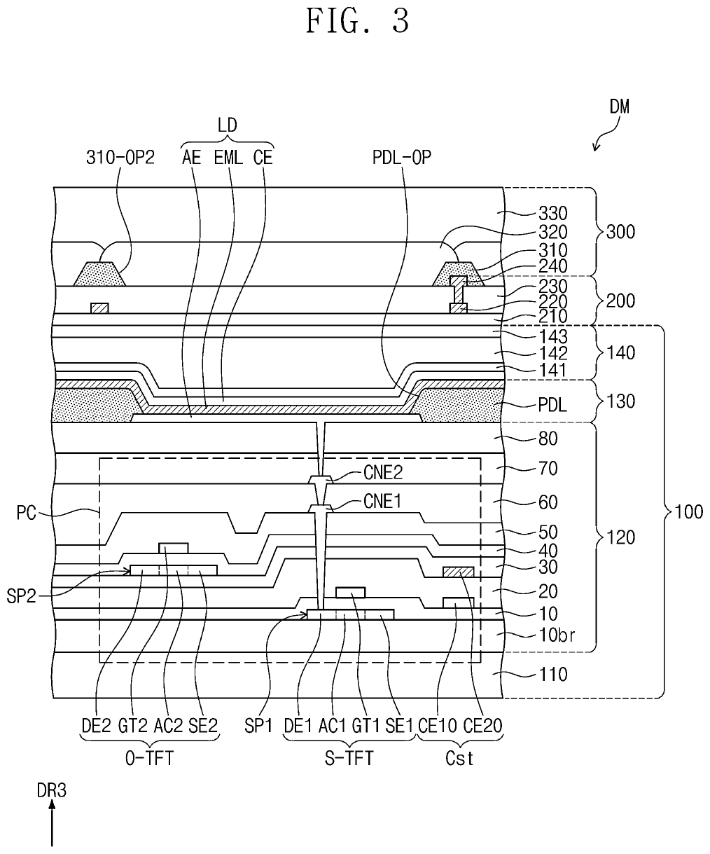

FIG. 3 is a cross-sectional view illustrating a portion of a display module according to an embodiment supported by aspects of the present disclosure. FIG. 3 illustrates a partial cross-section of one light emitting element LD and a pixel circuit PC that are included in a display module DM. Hereinafter, components of the display module DM according to this embodiment will be described in detail with reference to FIG. 3.

A display panel 100 included in the display module DM according to an embodiment may include a base substrate 110. The base substrate 110 may be a member that provides a base surface on which a circuit layer 120 is disposed. The base substrate 110 may be a glass substrate, a metal substrate, a plastic substrate, a silicon substrate, or the like. However, embodiments of the present disclosure are not limited thereto, and the base substrate 110 may be an inorganic layer, an organic layer, or a composite material layer.

A buffer layer 10br may be disposed on the base substrate 110. The buffer layer 10br may prevent a phenomenon in which metal atoms or impurities are dispersed from the base substrate 110 into a first semiconductor pattern SP1 above the buffer layer 10br. The first semiconductor pattern SP1 includes a channel region AC1 of a silicon transistor S-TFT. The buffer layer 10br may adjust a heat supply rate during a crystallization process of forming the first semiconductor pattern SP1 such that the first semiconductor pattern SP1 is uniformly formed.

The first semiconductor pattern SP1 may be disposed on the buffer layer 10br. The first semiconductor pattern SP1 may include a silicon semiconductor. For example, the silicon semiconductor may include amorphous silicon, polycrystalline silicon, monocrystalline silicon, or the like. For example, the first semiconductor pattern SP1 may include low-temperature polysilicon.

FIG. 3 illustrates a portion of the first semiconductor pattern SP1 disposed on the buffer layer 10br, and the first semiconductor pattern SP1 may be further disposed on another area. The first semiconductor pattern SP1 may be arranged over pixels according to a specific rule or target configuration. The first semiconductor pattern SP1 may have different electrical properties based on whether the first semiconductor pattern SP1 is doped or not. The first semiconductor pattern SP1 may include a first region with high conductivity and a second region with low conductivity. The first region may be doped with an n-type dopant or a p-type dopant. A p-type transistor may include a doped region doped with the p-type dopant, and an n-type transistor may include a doped region doped with the n-type dopant. The second region may be a non-doped region, or the second region may be doped to have a lower concentration than the first region.

The conductivity of the first region may be higher than the conductivity of the second region, and the first region may substantially serve as an electrode or a signal line. The second region may substantially correspond to an active area (or channel) of a transistor. In other words, one portion of the first semiconductor pattern SP1 may be an active area of the transistor, another portion of the first semiconductor pattern SP1 may be a source or a drain of the transistor, and still another portion of the first semiconductor pattern SP1 may be a connection electrode or a connection signal line.

A source region SE1 (or source), a channel region AC1 (or channel), and a drain region DE1 (or drain) of the silicon transistor S-TFT may be provided from the first semiconductor pattern SP1. The source region SE1 and the drain region DE1 may extend from the channel region AC1 in opposite directions on a cross-section.

Although not illustrated, a rear metal layer may be below each of the silicon transistor S-TFT and an oxide transistor O-TFT. The rear metal layer may be disposed to overlap the pixel circuit PC, and may block external light from reaching the pixel circuit PC. The rear metal layer may be disposed between the base substrate 110 and the buffer layer 10br. Alternatively, the rear metal layer may be disposed between a second insulation layer 20 and a third insulation layer 30.

The rear metal layer may include a reflective metal. For example, the rear metal layer may include silver (Ag), a silver-containing alloy, molybdenum (Mo), a molybdenum-containing alloy, aluminum (Al), an aluminum-containing alloy, an aluminum nitride (AlN), tungsten (W), a tungsten nitride (WN), copper (Cu), a p+ doped amorphous silicon, and the like. The rear metal layer may be connected to an electrode or a line, and the rear metal layer may receive a constant voltage or a signal from the electrode or the line. According to an embodiment supported by aspects of the present disclosure, the rear metal layer may be a floating electrode having a shape isolated from another electrode or line. In an embodiment supported by aspects of the present disclosure, an inorganic barrier layer may be further disposed between the base substrate 110 and the buffer layer 10br.

A first insulation layer 10 may be disposed on the buffer layer 10br. The first insulation layer 10 may overlap a plurality of pixels in common and cover the first semiconductor pattern SP1. The first insulation layer 10 may be an inorganic layer and/or an organic layer, and the first insulation layer 10 may have a single-layer or multilayer structure.

The first insulation layer 10 may include at least one of an aluminum oxide, a titanium oxide, a silicon oxide, a silicon nitride, a silicon oxynitride, a zirconium oxide, or a hafnium oxide. In this embodiment, the first insulation layer 10 may be a silicon oxide layer having a single-layer structure. In addition to the first insulation layer 10, an insulation layer of a circuit layer 120 to be described later may be an inorganic layer and/or an organic layer and may have a single-layer or multilayer structure. The inorganic layer may include at least one of the foregoing materials, but is not limited thereto.

A gate GT1 of the silicon transistor S-TFT is disposed on the first insulation layer 10. The gate GT1 may be a portion of a metal pattern. The gate GT1 overlaps the channel region AC1. The gate GT1 may function as a mask in a process of doping the first semiconductor pattern SP1. For example, the gate GT1 may include titanium (Ti), silver (Ag), a silver-containing alloy, molybdenum (Mo), a molybdenum-containing alloy, aluminum (Al), an aluminum-containing alloy, an aluminum nitride (AlN), tungsten (W), a tungsten nitride (WN), copper (Cu), an indium tin oxide (ITO), an indium zinc oxide (IZO), or the like, but is not particularly limited thereto.

The second insulation layer 20 may be disposed on the first insulation layer 10 and cover the gate GT1. The third insulation layer 30 may be disposed on the second insulation layer 20. A second electrode CE20 of a storage capacitor Cst may be disposed between the second insulation layer 20 and the third insulation layer 30. In some aspects, a first electrode CE10 of the storage capacitor Cst may be disposed between the first insulation layer 10 and the second insulation layer 20.

A second semiconductor pattern SP2 may be disposed on the third insulation layer 30. The second semiconductor pattern SP2 may include a channel region AC2 of the oxide transistor O-TFT to be described later. The second semiconductor pattern SP2 may include an oxide semiconductor. The second semiconductor pattern SP2 may include a transparent conductive oxide (TCO) such as, for example, an indium tin oxide (ITO), an indium zinc oxide (IZO), an indium gallium zinc oxide (IGZO), a zinc oxide (ZnO), or an indium oxide (In₂O₃).

The oxide semiconductor may include a plurality of regions divided according to whether the transparent conductive oxide is reduced or not. A region in which the transparent conductive oxide is reduced (hereinafter referred to as a reduced region) has higher conductivity than a region in which the transparent conductive oxide is not reduced (hereinafter referred to as a non-reduced region). The reduced region substantially serves as a source/drain or a signal line of a transistor. The non-reduced region substantially corresponds to a semiconductor region (or active area or channel) of the transistor. In other words, a partial area of the second semiconductor pattern SP2 may be the semiconductor region of the transistor, another partial area of the second semiconductor pattern SP2 may be a source region/a drain region of the transistor, and still another portion of the second semiconductor pattern SP2 may be a signal transfer area.

A source region SE2 (or source), a channel region AC2 (or channel), and a drain region DE2 (drain) of the oxide transistor O-TFT may be provided from the second semiconductor pattern SP2. The source region SE2 and the drain region DE2 may extend from the channel region AC2 in opposite directions on a cross-section.

A fourth insulation layer 40 may be disposed on the third insulation layer 30. The fourth insulation layer 40 may overlap the plurality of pixels in common and cover the second semiconductor pattern SP2. Although not illustrated, the fourth insulation layer 40 may be provided in the form of an insulation pattern that overlaps a gate GT2 of the oxide transistor O-TFT and exposes each of the source region SE2 and the drain region DE2 of the oxide transistor O-TFT.

The gate GT2 of the oxide transistor O-TFT is disposed on the fourth insulation layer 40. The gate GT2 of the oxide transistor O-TFT may be a portion of a metal pattern. The gate GT2 of the oxide transistor O-TFT overlaps the channel region AC2.

A fifth insulation layer 50 may be disposed on the fourth insulation layer 40 and cover the gate GT2. The first connection electrode CNE1 may be disposed on the fifth insulation layer 50. The first connection electrode CNE1 may be connected to the drain region DE1 of the silicon transistor S-TFT through a contact hole passing through the first to fifth insulation layers 10, 20, 30, 40 and 50.

A sixth insulation layer 60 may be disposed on the fifth insulation layer 50. A second connection electrode CNE2 may be disposed on the sixth insulation layer 60. The second connection electrode CNE2 may be connected to the first connection electrode CNE1 through a contact hole passing through the sixth insulation layer 60. A seventh insulation layer 70 may be disposed on the sixth insulation layer 60 and cover the second connection electrode CNE2. An eighth insulation layer 80 may be disposed on the seventh insulation layer 70.

Each of the sixth insulation layer 60, the seventh insulating layer 70, and the eighth insulation layer 80 may be an organic layer. For example, each of the sixth insulation layer 60, the seventh insulating layer 70, and the eighth insulation layer 80 may include a general purpose polymer such as, for example, benzocyclobutene (BCB), polyimide, hexamethyldisiloxane (HMDSO), polymethyl methacrylate (PMMA), or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, and a blend thereof.

The light emitting element LD may include a first electrode AE (or pixel electrode), an emission layer EML, and a second electrode CE (or common electrode). Each of the emission layer EML and the second electrode CE may be provided in the plurality of pixels in common.

The first electrode AE of the light emitting element LD may be disposed on the eighth insulation layer 80. The first electrode AE of the light emitting element LD may be a (semi-) transmissive electrode or a reflective electrode. According to an embodiment supported by aspects of the present disclosure, the first electrode AE of the light emitting element LD may include a reflective layer formed of Ag, Mg, Al, Pt, Pd, Au, Ni, Nd, Ir, Cr, or a compound thereof, and a transparent or semi-transparent electrode layer provided on the reflective layer. The transparent or semi-transparent electrode layer may include at least one selected from the group consisting of an indium tin oxide (ITO), an indium zinc oxide (IZO), an indium gallium zinc oxide (IGZO), a zinc oxide (ZnO) or an indium oxide (In₂O₃), and an aluminum-doped zinc oxide (AZO). For example, the first electrode AE of the light emitting element LD may include a stacked structure of ITO/Ag/ITO.

A pixel defining film PDL may be disposed on the eighth insulation layer 80. The pixel defining film PDL may include the same material, and be formed through the same process. The pixel defining film PDL may have a light absorbing property, and for example, the pixel defining film PDL may have a black color. The pixel defining film PDL may include a black coloring agent. The black coloring agent may include a black dye or a black pigment. The black coloring agent may include a carbon black, a metal such as, for example, chrome, or an oxide thereof. The pixel defining film PDL may correspond to a light blocking pattern having a light blocking property.

The pixel defining film PDL may cover a portion of the first electrode AE of the light emitting element LD. For example, an opening PDL-OP that exposes a portion of the first electrode AE of the light emitting element LD may be defined in the pixel defining film PDL. The pixel defining film PDL may increase a distance between the second electrode CE and an edge of the first electrode AE of the light emitting element LD. Thus, for example, the pixel definition film PDL may serve to prevent an arc or the like from occurring at the edge of the first electrode AE.

Although not illustrated, a hole control layer may be disposed between the first electrode AE and the emission layer EML. The hole control layer may include a hole transport layer and a hole injection layer. An electron control layer may be disposed between the emission layer EML and the second electrode CE. The electron control layer may include an electron transport layer and an electron injection layer. The hole control layer and the electron control layer may be formed, in common, in the plurality of pixels by using an open mask.

An encapsulation layer 140 may be disposed on the light emitting element layer 130. The encapsulation layer 140 may include an inorganic layer 141, an organic layer 142, and an inorganic layer 143 that are stacked in sequence, but layers constituting the encapsulation layer 140 are not limited thereto.

The inorganic layers 141 and 143 may protect the light emitting element layer 130 from moisture and oxygen, and the organic layer 142 may protect the light emitting element layer 130 from foreign matter such as, for example, dust particles. The inorganic layers 141 and 143 may include a silicon nitride layer, a silicon oxynitride layer, a silicon oxide layer, a titanium oxide layer, an aluminum oxide layer, or the like. The organic layer 142 may include an acrylic organic layer, and is not limited thereto.

A sensor layer 200 may be disposed on the display panel 100. The sensor layer 200 may be referred to as a sensor, an input detection layer, or an input detection panel. The sensor layer 200 may include a sensor base layer 210, a first conductive layer 220, a detection insulation layer 230, and a second conductive layer 240.

The sensor base layer 210 may be disposed directly on the display panel 100. The sensor base layer 210 may be an inorganic layer including at least one of a silicon nitride, a silicon oxynitride, or a silicon oxide. Alternatively, the sensor base layer 210 may be an organic layer including an epoxy resin, an acrylic resin, or an imide-based resin. The sensor base layer 210 may have a single-layer structure. In another example, the sensor base layer 210 may have a multilayer structure in which layers are stacked in the third direction DR3.

Each of the first conductive layer 220 and the second conductive layer 240 may have a single-layer structure. In another example, each of the first conductive layer 220 and the second conductive layer 240 may have a multilayer structure in which layers are stacked in the third direction DR3. The first conductive layer 220 and the second conductive layer 240 may include conductive lines that define a mesh-shaped detection electrode. The conductive lines may not overlap the opening PDL-OP, and the conductive lines may overlap the pixel defining film PDL.

The conductive layer having a single-layer structure may include a metal layer or a transparent conductive layer. The metal layer may include molybdenum, silver, titanium, copper, aluminum, or an alloy thereof. The transparent conductive layer may include a transparent conductive oxide such as, for example, an indium tin oxide (ITO), an indium zinc oxide (IZO), a zinc oxide (ZnO), or an indium zinc tin oxide (IZTO). In some aspects, the transparent conductive layer may include a conductive polymer such as, for example, PEDOT, metal nanowire, graphene, or the like.

The conductive layer having a multilayer structure may include metal layers. The metal layers may have, for example, a three-layer structure of titanium/aluminum/titanium. The conductive layer having a multilayer structure may include at least one metal layer and at least one transparent conductive layer.

The detection insulation layer 230 may be disposed between the first conductive layer 220 and the second conductive layer 240. The detection insulation layer 230 may include an inorganic film. The inorganic film may include at least one of an aluminum oxide, a titanium oxide, a silicon oxide, a silicon nitride, a silicon oxynitride, a zirconium oxide, or a hafnium oxide.

Alternatively, the detection insulation layer 230 may include an organic film. The organic film may include at least one of acryl-based resin, a methacryl-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

An optical layer 300 may be disposed on the sensor layer 200. The optical layer 300 may include a light blocking pattern 310, a color filter 320, and a planarization layer 330.

The optical layer 300 may reduce external light reflectance. The optical layer 300 may include the color filter 320. The color filter 320 may be provided in plurality, and the plurality of color filters 320 may be disposed according to a predetermined arrangement based on the color of light emitted by pixels included in the display panel 100. In the display module DM according to an embodiment, the optical layer 300 may not include a retarder and a polarizer, and the optical layer 300 may reduce reflectance of the display module DM through the color filter 320. In the display module DM according to an embodiment, the optical layer 300 may not include a polarizing film or a polarizing layer.

A material constituting the light blocking pattern 310 is not particularly limited as long as the material is a material that absorbs light. The light blocking pattern 310 may be a layer having a black color, and in an embodiment, the light blocking pattern 310 may include a black coloring agent. The black coloring agent may include a black dye or a black pigment. The black coloring agent may include a carbon black, a metal such as, for example, chrome, or an oxide thereof.

The light blocking pattern 310 may cover the second conductive layer 240 of the sensor layer 200. The light blocking pattern 310 may prevent external light from being reflected due to the second conductive layer 240. The light blocking pattern 310 may overlap a portion of the pixel defining film PDL.

A division opening 310-OP2 may be defined in the light blocking pattern 310. The division opening 310-OP2 may overlap the first electrode AE of the light emitting element LD. Regarding the color filters 320, each color filter 320 may overlap the first electrode AE of the light emitting element LD which corresponds to the color filter 320. Regarding the color filters 320, each color filter 320 may cover the division opening 310-OP2 corresponding to the color filter 320. Each of the plurality of color filters 320 may be in contact with the light blocking pattern 310.

The planarization layer 330 may cover the light blocking pattern 310 and the plurality of color filters 320. The planarization layer 330 may include organic matter, and a flat surface may be provided on a top surface of the planarization layer 330. In an embodiment supported by aspects of the present disclosure, the planarization layer 330 may be omitted.

FIGS. 4A to 4D are cross-sectional views of a window according to an embodiment supported by aspects of the present disclosure.

Referring to FIG. 4A, a window WM according to an embodiment supported by aspects of the present disclosure includes a base layer BL, and an anti-reflection layer ARL disposed on the base layer BL.

The base layer BL may include a transparent material. In an embodiment, the base layer BL may be a glass substrate or a polymer film. In an embodiment, the base layer BL may be a chemically strengthened glass substrate. In an example in which the base layer BL is a chemically strengthened glass substrate, use of the chemically strengthened glass substrate may support a reduction in thickness and increased mechanical strength of the base layer BL. Accordingly, the base layer BL may be used for a window of a foldable display device.

In an example in which the base layer BL includes a polymer film, the base layer BL may include a polyimide (PI) film or a polyethylene terephthalate (PET) film. The base layer BL of the window WM may have a multilayer structure or a single-layer structure. For example, the base layer BL may have a structure in which a plurality of polymer films are coupled to each other through an adhesive member, or the base layer BL may have a structure in which a glass substrate and a polymer film are coupled to each other through an adhesive. The base layer BL may be formed of a flexible material.

The base layer BL may have a thickness of, for example, about 20 μm to about 60 μm. Preferably, the thickness of the base layer BL may range from about 20 μm to about 40 μm. Although FIGS. 4A to 4D illustrate examples in which the base layer BL has a rectangular shape on a cross-section, the base layer BL is not limited thereto. For example, the base layer BL according to an embodiment may have a shape in which an edge portion of a top surface of the base layer BL is rounded by a curved surface. More specifically, the edge portion of the top surface, which overlaps the bezel area BZA (see FIG. 1B), a shape of the base layer BL may be rounded by a curved surface.

The anti-reflection layer ARL includes a first layer L1, a second layer L2, and a third layer L3. In the window WM according to an embodiment, the base layer BL, the first layer L1, the second layer L2, and the third layer L3 may be stacked in sequence.

The first layer L1 may be disposed on the base layer BL. In this embodiment, the first layer L1 may be disposed directly on the base layer BL. A bottom surface of the first layer L1 may be in contact with a top surface of the base layer BL.

The first layer L1 may have a higher refractive index than the base layer BL. The first layer L1 may have a higher refractive index than the second layer L2 to be described later. The first layer L1 may have the highest refractive index among layers of the anti-reflection layer ARL. The refractive index of the first layer L1 may range from about 1.7 to about 2.5. A “refractive index” of a layer described herein may mean a “refractive index of the layer in a wavelength of about 550 nm.” For example, the refractive index of the first layer L1 in the wavelength of about 550 nm may range from about 1.7 to about 2.5. In another example, the refractive index of the first layer L1 may range from about 1.9 to about 2.3. Due to high refractive characteristics of the first layer L1, surface reflectance of the window WM may be reduced. The structure of the window WM according to this embodiment, in which the first layer L1 having high refractive characteristics is stacked on the base layer B1, and the second layer L2 having low refractive characteristics and the third layer L3 having high refractive characteristics are stacked in sequence on the first layer L1, may support a reduced surface reflectance of the window WM.

The first layer L1 may include a first material. The first material includes silicon (Si), aluminum (Al), and nitrogen (N) atoms. The first material may include an aluminum silicon nitride. The first material may include a metal nanocomposite comprising silicon, aluminum, and nitrogen atoms. The first material may include an Al—Si—N nanocomposite. The first material may include an aluminum silicon oxynitride. The first material may include a material to which an aluminum silicon nitride is oxidized. The first material may include a material to which at least a portion of a nanocomposite comprising silicon, aluminum, and nitrogen atoms is oxidized. Alternatively, the first material may include both an aluminum silicon nitride and an aluminum silicon oxynitride.

An atomic percent of silicon in the first material may range from about 5 at % to about 20 at %. In a comparative example in which the atomic percent of silicon in the first material is greater than about 20 at %, a metal nitride lattice may be changed, and accordingly, a thin film stress of the first layer L1 including the first material may be increased, reducing reliability of the window. In an example in which the first material includes oxygen atoms, an atomic percent of oxygen may be about 20 at % or less. In a comparative example in which the atomic percent of oxygen in the first material is greater than about 20 at %, the high refractive characteristics of the first layer L1 including the first material may be decreased, reducing the reliability of the window.

The first layer L1 may have a single-layer structure. That is, in some examples, the first layer L1 may not include a plurality of layers. The first layer L1 may be a single layer including the first material as described herein.

The first layer L1 may be formed by reactive sputtering. For example, the first layer L1 may be formed by radio frequency sputtering. The first layer L1 may be formed by radio frequency sputtering in which aluminum and silicon are included as target materials and nitrogen gas (N₂) is added as reactive gas. The first layer L1 may be formed by radio frequency sputtering in which an aluminum-silicon alloy is included as a target material and nitrogen gas is added as reactive gas. As the first layer L1 is formed by the sputtering described herein, the first layer L1 may include the first material. However, the method for forming the first layer L1 is not limited to the methods described herein. For example, the first layer L1 may be formed to include the first material through various evaporation methods such as, for example, a thermal evaporation process or an e-beam evaporation process.

The first layer L1 has a first thickness d1 in the third direction DR3. The first thickness d1 may range from about 10 nm to about 50 nm. For example, the first thickness d1 may range from about 15 nm to about 25 nm. In a comparative example in which the first thickness d1 is less than 10 nm, the surface reflectance of the window WM may not be reduced sufficiently (e.g., the surface reflectance may fail to satisfy a target surface reflectance). In a comparative example in which the first thickness d1 is greater than 50 nm, reflective colors of the window WM may be affected, and the total thickness of the display device DD may excessively increase or exceed a target thickness of the display device DD (see FIG. 1A).

The second layer L2 may be disposed on the first layer L1. In an embodiment, the second layer L2 may be disposed directly on the first layer L1. A bottom surface of the second layer L2 may be in contact with a top surface of the first layer L1.

The second layer L2 may have a lower refractive index than the first layer L1. For example, the refractive index of the second layer L2 in the wavelength of about 550 nm may range from about 1.3 to about 1.7. In an example, the refractive index of the second layer L2 in the wavelength of about 550 nm may range from about 1.41 to about 1.56. Due to the low refractive characteristics of the second layer L2, the surface reflectance of the window WM may be reduced.

The second layer L2 includes a second material. The second material includes a silicon oxide. The second material may include a silicon dioxide (SiO₂). In an embodiment, the second layer L2 may have a single-layer structure. That is, in some examples, the second layer L2 may not include a plurality of layers. The second layer L2 may be a single layer including the second material. For example, the second layer L2 may have a single-layer structure formed of a silicon dioxide (SiO₂).

The second layer L2 may be formed by sputtering. For example, the second layer L2 may be formed by radio frequency sputtering. However, the method for forming the second layer L2 is not limited to the methods described herein. For example, the second layer L2 may be formed to include the second material through various evaporation methods such as, for example, thermal evaporation process or an e-beam evaporation process.

The second layer L2 has a second thickness d2 in the third direction DR3. The second thickness d2 may range from about 10 nm to about 50 nm. For example, the second thickness d2 may range from about 18 nm to about 33 nm. In a comparative example in which the second thickness d2 is less than 10 nm, the surface reflectance of the window WM may not be reduced sufficiently (e.g., the surface reflectance may fail to satisfy a target surface reflectance). In a comparative example in which the second thickness d2 is greater than 50 nm, the reflective colors of the window WM may be affected, and the total thickness of the display device DD may excessively increase or exceed a target thickness of the display device DD (see FIG. 1A).

The third layer L3 may be disposed on the second layer L2. In an embodiment, the third layer L3 may be disposed directly on the second layer L2. A bottom surface of the third layer L3 may be in contact with a top surface of the second layer L2.

The third layer L3 may have a higher refractive index than the second layer L2. The refractive index of the third layer L3 may be substantially the same as the refractive index of the first layer L1. The refractive index of the third layer L3 may range from about 1.7 to about 2.5. For example, the refractive index of the third layer L3 in the wavelength of about 550 nm may range from about 1.9 to about 2.3.

The third layer L3 includes the first material. The third layer L3 may include the same material as the material included in the first layer L1. The third layer L3 may have a single-layer structure. That is, in some examples, the third layer L3 may not include a plurality of layers. The third layer L3 may be a single layer including the first material.

The third layer L3 may be formed by reactive sputtering. The third layer L3 may be formed through the same process as the process of forming the first layer L1.

The third layer L3 has a third thickness d3 in the third direction DR3. The third layer L3 may be formed through the same process as the first layer L1 and may include the same material as the material included in the first layer L1, but in some examples, the third thickness d3 may be different from the first thickness d1. A ratio of the first thickness d1 to the third thickness d3 may range from about 0.01 to about 0.1. For example, the ratio of the first thickness d1 to the third thickness d3 may range from about 0.02 to about 0.07. A ratio of the second thickness d2 to the third thickness d3 may range from about 0.01 to about 0.1. For example, the ratio of the second thickness d2 to the third thickness d3 may range from about 0.03 to about 0.08.

The third thickness d3 may range from about 400 nm to about 500 nm. For example, the third thickness d3 may range from about 410 nm to about 490 nm. In a comparative example in which the third thickness d3 is less than 400 nm, a hardness value of the anti-reflection layer ARL may be relatively decreased, reducing the reliability of the window WM. In an example in which the third thickness d3 is greater than 500 nm, the reflective colors of the window WM may be affected, and the total thickness of the display device DD may excessively increase or exceed a target thickness of the display device DD (see FIG. 1A).

Referring to FIG. 4B, a window WM-1 according to an embodiment supported by aspects of the present disclosure includes an anti-reflection layer ARL-1. In an embodiment, the anti-reflection layer ARL-1 may include the first to third layers L1, L2 and L3 described herein and further include fourth to sixth layers L4, L5 and L6. In the anti-reflection layer ARL-1 according to an embodiment, the fourth to sixth layers L4, L5 and L6 may be stacked in sequence on the third layer L3.

The fourth layer LA may be disposed on the third layer L3. In an embodiment, the fourth layer L4 may be disposed directly on the third layer L3. A bottom surface of the fourth layer L4 may be in contact with a top surface of the third layer L3.

The fourth layer L4 may have a lower refractive index than the third layer L3. The refractive index of the fourth layer L4 may be substantially the same as the refractive index of the second layer L2. The refractive index of the fourth layer L4 may range from about 1.4 to about 1.6. For example, the refractive index of the fourth layer L4 in the wavelength of about 550 nm may range from about 1.41 to about 1.56. The fourth layer L4 may include the second material. The fourth layer

L4 may include the same material as the material included in the second layer L2. The fourth layer L4 may have a single-layer structure. That is, in some examples, the fourth layer L4 may not include a plurality of layers. The fourth layer L4 may be a single layer including the second material.

The fourth layer L4 has a fourth thickness d4 in the third direction DR3. The fourth layer L4 may be formed through the same process as the second layer L2 and may include the same material as the material included in the second layer L2, but in some examples, the fourth thickness d4 may be different from the second thickness d2. The fourth thickness d4 may range from about 5 nm to about 15 nm.

The fourth layer L4 may be formed by sputtering. The fourth layer L4 may be formed through the same process as the process of forming the second layer L2.

The fifth layer L5 may be disposed on the fourth layer L4. In an embodiment, the fifth layer L5 may be disposed directly on the fourth layer L4. A bottom surface of the fifth layer L5 may be in contact with a top surface of the fourth layer L4.

The fifth layer L5 may have a lower refractive index than the fourth layer L4. The refractive index of the fifth layer L5 may be substantially the same as each of the refractive index of the first layer L1 and the refractive index of the third layer L3. The refractive index of the fifth layer L5 may range from about 1.9 to about 2.5. For example, the refractive index of the fifth layer L5 in the wavelength of about 550 nm may range from about 1.9 to about 2.3.

The fifth layer L5 may include the first material. The fifth layer L5 may include the same material as each of the material included in the first layer L1 and the material included in the third layer L3. The fifth layer L5 may have a single-layer structure. That is, in some examples, the fifth layer L5 may not include a plurality of layers. The fifth layer L5 may be a single layer including the first material.

The fifth layer L5 has a fifth thickness d5 in the third direction DR3. The fifth layer L5 may be formed through the same process as the first layer L1 and the third layer L3 and may include the same material as each of the material included in the first layer L1 and the material included in the third layer L3, but in some examples, the fifth thickness d5 may be different from each of the first thickness d1 and the third thickness d3. The fifth thickness d5 may range from about 100 nm to about 200 nm. For example, the fifth thickness d5 may range from about 130 nm to about 160 nm.

The fifth layer L5 may be formed by reactive sputtering. The fifth layer L5 may be formed through the same process as each of the process of forming the first layer L1 and the process of forming the third layer L3.

The sixth layer L6 may be disposed on the fifth layer L5. In an embodiment, the sixth layer L6 may be disposed directly on the fifth layer L5. A bottom surface of the sixth layer L6 may be in contact with a top surface of the fifth layer L5.

The sixth layer L6 may have a lower refractive index than the fifth layer L5. The refractive index of the sixth layer L6 may be substantially the same as the refractive index of the fourth layer L4. The refractive index of the sixth layer L6 may range from about 1.4 to about 1.6. For example, the refractive index of the sixth layer L6 in the wavelength of about 550 nm may range from about 1.41 to about 1.56.

The sixth layer L6 may include the second material. The sixth layer L6 may include the same material as each of the material included in the second layer L2 and the material included in the fourth layer L4. The sixth layer L6 may have a single-layer structure. The sixth layer L6 may be a single layer including the second material.

The sixth layer L6 has a sixth thickness d6 in the third direction DR3. The sixth layer L6 may be formed through the same process as the second layer L2 and the fourth layer L4 and may include the same material as each of the material included in the second layer L2 and the material included in the fourth layer L4, but in some examples, the sixth thickness d6 may be different from each of the second thickness d2 and the fourth thickness d4. The sixth thickness d6 may range from about 40 nm to about 100 nm. For example, the sixth thickness d6 may range from about 72 nm to about 98 nm.

The sixth layer L6 may be formed by sputtering. The sixth layer L6 may be formed through the same process as each of the process of forming the second layer L2 and the process of forming the fourth layer L4.

The anti-reflection layer ARL-1 may have hardness of about 20 GPa or greater when measured using a nano-indenter through a Berkovich indenter hardness test at an indentation depth of about 100 nm. The hardness of the anti-reflection layer ARL-1, which is measured at the indentation depth of 100 nm, may range from about 23 GPa to about 40 GPa. The hardness of the anti-reflection layer ARL-1 may range from about 15 GPa to about 50 GPa when measured using the nano-indenter through the Berkovich indenter hardness test at an indentation depth ranging from about 50 nm to about 150 nm. As the anti-reflection layer ARL-1 includes the first layer L1 including the first material and having the first thickness d1, the second layer L2 including the second material and having the second thickness d2, and the third layer L3 including the first material and having the third thickness d3, the anti-reflection layer ARL-1 may have a high hardness value (e.g., a hardness value exceeding a threshold value). Accordingly, the window WM-1 including the anti-reflection layer ARL-1 may have improved reliability.

The anti-reflection layer ARL-1 may have residual stress of about 2 GPa or less at a temperature of about 28° C. The anti-reflection layer ARL-1 may have residual stress of about 0.1 GPa to about 2 GPa at the temperature of about 28° C. For example, the anti-reflection layer ARL-1 may have residual stress of about 0.1 GPa to about 1 GPa at the temperature of about 28° C. As the anti-reflection layer ARL-1 includes the first layer L1 including the first material and having the first thickness d1, the second layer L2 including the second material and having the second thickness d2, and the third layer L3 including the first material and having the third thickness d3, the anti-reflection layer ARL-1 may have a low residual stress value. Accordingly, the window WM-1 including this anti-reflection layer ARL-1 may have improved reliability.

Referring to FIG. 4C, a window WM-2 according to an embodiment supported by aspects of the present disclosure may further include an anti-fingerprint layer AF disposed on an anti-reflection layer ARL-1.

The anti-fingerprint layer AF may be a layer that improves slip properties and scratch resistance of a surface, and the like. The anti-fingerprint layer AF may have excellent anti-fingerprint properties and suppress surface wear. The anti-fingerprint layer AF may be a functional layer in which an anti-fingerprint material is added to a hard coating material. The anti-fingerprint layer AF may include a fluorine-containing compound. For example, the anti-fingerprint layer AF may include a perfluoropolyether (PFPE) compound. Alternatively, the anti-fingerprint layer AF may include a silane compound containing perfluoropolyether. The anti-fingerprint layer AF may have a thickness of about 10 nm to about 40 nm. The anti-fingerprint layer AF may be formed through one of an e-beam evaporation process, a thermal evaporation process, and a sputtering process.

Although not illustrated in FIG. 4C, the window according to an embodiment supported by aspects of the present disclosure may further include a separate adhesive layer between the anti-fingerprint layer AF and the anti-reflection layer ARL-1. For example, the window according to an embodiment may further include an adhesive layer such as, for example, an optically clear adhesive (OCA) and/or a pressure sensitive adhesive (PSA), between the anti-fingerprint layer AF and the anti-reflection layer ARL-1. However, the window according to the embodiment is not limited thereto.

Referring to FIG. 4D, a window WM-3 according to an embodiment supported by aspects of the present disclosure includes an anti-reflection layer ARL-2. In an embodiment, the anti-reflection layer ARL-2 according to another embodiment may include the first to fifth layers L1, L2, L3, L4 and L5 described herein, and a sixth layer L6-1.

In an embodiment, the sixth layer L6-1 may include a plurality of layers. The sixth layer L6-1 may include a planarization layer PL and a columnar layer CL. The sixth layer L6-1 may include the planarization layer PL and the columnar layer CL that are disposed in sequence on the fifth layer L5. The sixth layer L6-1 may have a two-layer structure including the planarization layer PL disposed directly on the fifth layer L5, and the columnar layer CL disposed directly on the planarization layer PL.

The sixth layer L6-1 may have a lower refractive index than the fifth layer L5. The refractive index of the planarization layer PL may be substantially the same as the refractive index of the fourth layer L4. The refractive index of the planarization layer PL may range from about 1.4 to about 1.6. For example, the refractive index of the planarization layer PL in the wavelength of about 550 nm may range from about 1.41 to about 1.56. The columnar layer CL may have a lower refractive index than the planarization layer PL. The refractive index of the columnar layer CL may range from about 1.3 to about 1.5. For example, the refractive index of the columnar layer CL in the wavelength of about 550 nm may range from about 1.32 to about 1.50.

The sixth layer L6-1 may include the second material. The sixth layer L6-1 may include the same material as each of the material included in the second layer L2 and the material included in the fourth layer L4. Each of the planarization layer PL and the columnar layer CL may include the second material. For example, each of the planarization layer PL and the columnar layer CL may include a silicon dioxide (SiO₂).

In the sixth layer L6-1, the planarization layer PL may have a seventh thickness dₐ in the third direction DR3. The seventh thickness dₐ may be about 20 nm or less. For example, the seventh thickness dₐ may range from about 4 nm to about 15 nm. The columnar layer CL may have an eighth thickness d_{b} in the third direction DR3. The eighth thickness d_{b} may range from about 50 nm to about 100 nm. For example, the eighth thickness d_{b} may range from about 72 nm to about 98 nm.

In the sixth layer L6-1, surface roughness of a top surface of the columnar layer CL may be greater than surface roughness of a top surface of the planarization layer PL. A plurality of uneven portions may be defined in the top surface of the columnar layer CL unlike the top surface of the planarization layer PL.

In the sixth layer L6-1, the columnar layer CL may be formed through an e-beam evaporation process. The columnar layer CL may be formed of the second material through the e-beam evaporation process, and the planarization layer PL may be formed of the second material through sputtering. As the columnar layer CL is formed through the e-beam evaporation process, the columnar layer CL may have a columnar structure. The second material included in the columnar layer CL may be formed to have a vertical structure along a columnar domain through the e-beam evaporation process. Accordingly, the surface roughness of the top surface of the columnar layer CL may be relatively greater than the surface roughness of the planarization layer PL.

Hereinafter, characteristic evaluation results of a window according to an embodiment supported by aspects of the present disclosure will be described with reference to FIGS. 4A to 4D, Examples, and a Comparative Example. Each of Examples described herein is provided as one example for helping understanding supported by aspects of the present disclosure, and the scope supported by aspects of the present disclosure is not limited thereto.

### (Manufacture of Window)

Examples 1 to 4 and the Comparative Example were each manufactured to have a structure of the window WM-1 in FIG. 4B, which includes the base layer BL and the anti-reflection layer ARL-1. Table 1 illustrates the material and the thicknesses of each of the layers L1, L2, L3, L4, L5 and L6 included in the anti-reflection layer ARL-1 according to each of Examples 1 to 4 and the Comparative Example. Examples 1 to 4 and the Comparative Example were manufactured to be the same as each other except for thickness values of the specific layers L1, L2, L3, L4, L5 and L6 included in the anti-reflection layer ARL-1.

In the materials included in the anti-reflection layer ARL-1 according to each of Examples 1 to 4 and the Comparative Example, an Al—Si—N nanocomposite was used as the first material, and a silicon dioxide (SiO₂) was used as the second material.

TABLE 1

| | | Thickness | |
|---|---|---|---|
| | Layer | value (nm) | Material included |
| Example 1 | Sixth layer L6 | 72 | Second material |
| | Fifth layer L5 | 130 | First material |
| | Fourth layer L4 | 5 | Second material |
| | Third layer L3 | 410 | First material |
| | Second layer L2 | 18 | Second material |
| | First layer L1 | 15 | First material |
| Example 2 | Sixth layer L6 | 98 | Second material |
| | Fifth layer L5 | 160 | First material |
| | Fourth layer L4 | 15 | Second material |
| | Third layer L3 | 490 | First material |
| | Second layer L2 | 33 | Second material |
| | First layer L1 | 25 | First material |
| Example 3 | Sixth layer L6 | 86.47 | Second material |
| | Fifth layer L5 | 146.78 | First material |
| | Fourth layer L4 | 9.88 | Second material |
| | Third layer L3 | 454.27 | First material |
| | Second layer L2 | 25.78 | Second material |
| | First layer L1 | 20.17 | First material |
| Example 4 | Sixth layer L6 | 98 | Second material |
| | Fifth layer L5 | 130 | First material |
| | Fourth layer L4 | 10 | Second material |
| | Third layer L3 | 450 | First material |
| | Second layer L2 | 18 | Second material |
| | First layer L1 | 25 | First material |
| Comparative | Sixth layer L6 | 86.47 | Second material |
| Example | Fifth layer L5 | 146.78 | First material |
| | Fourth layer L4 | 9.88 | Second material |
| | Third layer L3 | 300 | First material |
| | Second layer L2 | 60 | Second material |
| | First layer L1 | 50 | First material |

(Characteristic Evaluation of Window) The window characteristic evaluation results of Examples and the Comparative Example are illustrated in Table 2 below. In the characteristic evaluation of the windows in Table 2, each of reflectance for light having a wavelength of about 550 nm, transmittance for the light having the wavelength of about 550 nm, reflectance for light having a wavelength of about 400 nm to about 700 nm, and transmittance for the light having the wavelength of about 400 nm to about 700 nm is indicated by percent (%). The measured reflectance may be defined as a ratio of light reflected to the outside of the window to light incident in a direction from the outside of the window to the inside of the window. The light reflected to the outside may include both of regular reflection light, which is light reflected at the same angle after being incident, and diffuse reflection light, which is light scattered and reflected in various directions.

TABLE 2

| | | Reflectance | Trans- | Trans- |
|---|---|---|---|---|
| | Reflectance | (about 400- | mittance | mittance |
| | (about 550 | about 700 | (about 550 | (about 400- |
| | nm) | nm) | nm) | about 700 nm) |
| Example 1 | 4.76 | 5.82 | 95.02 | 93.89 |
| Example 2 | 4.88 | 5.30 | 94.86 | 94.35 |
| Example 3 | 4.48 | 4.93 | 95.28 | 94.76 |
| Example 4 | 5.61 | 5.65 | 94.16 | 94.05 |
| Comparative | 15.84 | 16.06 | 83.95 | 83.66 |
| Example | | | | |

Referring to the results in Table 2, it may be confirmed that the windows according to the Examples provide improvements of relatively low reflectance for visible light and relatively high transmittance when compared to the window according to Comparative Example. Accordingly, the window according to an embodiment supported by aspects of the present disclosure may have reduced reflectance for external light, and thus the visibility of a user using the window may be improved. In some aspects, a display device including the window according to an embodiment supported by aspects of the present disclosure includes the window with the improved reflection prevention characteristics, and the display device provides improved reliability. Referring to Tables 1 and 2, the window according to an embodiment supported by aspects of the present disclosure includes the anti-reflection layer, the anti-reflection layer has a structure in which the first layer including the first material and having the first thickness, the second layer including the second material and having the second thickness, and the third layer including the first material and having the third thickness are stacked. As the first layer, the second layer, and the third layer are included, the window according to an embodiment supported by aspects of the present disclosure and the display device including the window may have reduced reflectance for the visible light, and increased transmittance. Accordingly, the window and the display device may provide improved visibility.

In contrast, the thicknesses of the first to third layers according to Comparative Example are different from the first to third thicknesses of Examples 1 to 4, respectively. Accordingly, it is understood that Comparative Example has a higher reflectance and lower transmittance compared to Examples 1 to 4.

According to an embodiment supported by aspects of the present disclosure, the window may include the anti-reflection layer including the first to third layers each having a specific material and a specific thickness described herein, which supports improved reflection prevention characteristics. Accordingly, the durability and the reliability of the display device including the window may be improved.

Although some example embodiments of the present invention have been described, it is understood that the present invention should not be limited to the example embodiments, and various changes and modifications can be made by one ordinary skilled in the art within the spirit and scope of the present invention as hereinafter claimed. Therefore, the technical scope supported by aspects of the present disclosure is not limited to the contents described in the detailed description of the specification, but should be determined by the claims.

What is claimed is:

1. A window comprising:
a base layer; and
an anti-reflection layer disposed on the base layer,
wherein the anti-reflection layer comprises:
a first layer comprising a first material and having a first thickness;
a second layer comprising a second material and having a second thickness; and
a third layer comprising the first material and having a third thickness,
wherein:
the first material comprises silicon (Si), aluminum (Al), and nitrogen (N) atoms,
the second material comprises a silicon oxide,
each of the first thickness and the second thickness ranges from about 10 nm to about 50 nm, and
the third thickness ranges from about 400 nm to about 500 nm.

2. The window of claim 1, wherein:
each of the first layer and the third layer has a refractive index ranging from about 1.7 to about 2.5, and
the second layer has a refractive index ranging from about 1.3 to about 1.7.

3. The window of claim 1, wherein:
the first layer is disposed directly on the base layer,
the second layer is disposed directly on the first layer, and
the third layer is disposed directly on the second layer.

4. The window of claim 1, wherein the anti-reflection layer further comprises a fourth layer disposed directly on the third layer and comprising the second material,
wherein the fourth layer has a refractive index ranging from about 1.4 to about 1.6.

5. The window of claim 4, wherein the fourth layer has a fourth thickness ranging from about 5 nm to about 15 nm.

6. The window of claim 4, wherein the anti-reflection layer further comprises:
a fifth layer disposed directly on the fourth layer and comprising the first material; and
a sixth layer disposed directly on the fifth layer and comprising the second material,
wherein:
the fifth layer has a refractive index of about 1.9 to about 2.5, and
the sixth layer has a refractive index ranging from about 1.4 to about 1.6.

7. The window of claim 6, wherein:
the fifth layer has a fifth thickness ranging from about 100 nm to about 200 nm, and
the sixth layer has a sixth thickness ranging from about 40 nm to about 100 nm.

8. The window of claim 6, wherein the sixth layer comprises:
a planarization layer disposed on the fifth layer; and
a columnar layer disposed on the planarization layer,
wherein:
a plurality of uneven portions are provided on a top surface of the columnar layer, and
a surface roughness of the top surface of the columnar layer is greater than a surface roughness of a top surface of the planarization layer.

9. The window of claim 8, wherein:
the planarization layer has a refractive index ranging from about 1.4 to about 1.6, and
the columnar layer has a refractive index ranging from about 1.3 to about 1.5.

10. The window of claim 8, wherein:
the planarization layer has a thickness of about 20 nm or less, and
the columnar layer has a thickness ranging from about 50 nm to about 100 nm.

11. The window of claim 1, wherein an atomic percent of silicon in the first material ranges from about 5 at % to about 20 at %.

12. The window of claim 1, wherein the first material comprises a metal nanocomposite comprising aluminum, silicon, and nitrogen atoms.

13. The window of claim 1, wherein the first material comprises an aluminum silicon oxynitride.

14. The window of claim 13, wherein an atomic percent of oxygen in the first material is about 20 at % or less.

15. The window of claim 1, wherein:
each of the first layer and the third layer is a single layer comprising the first material, and
the second layer is a single layer comprising the second material.

16. The window of claim 1, wherein the anti-reflection layer has a hardness of about 20 GPa or greater at an indentation depth of about 100 nm.

17. The window of claim 1, wherein the anti-reflection layer has stress of about 2 GPa or less at a temperature of about 28° C.

18. The window of claim 1, further comprising an anti-fingerprint layer disposed on the anti-reflection layer.

19. A display device comprising:
a display module; and
a window disposed on the display module and comprising an anti-reflection layer,
wherein the anti-reflection layer comprises:
a first layer comprising a first material and having a refractive index ranging from about 1.7 to about 2.5;
a second layer comprising a second material and having a refractive index ranging from about 1.3 to about 1.7; and
a third layer comprising the first material and having a refractive index ranging from about 1.7 to about 2.5,
wherein:
the first material comprises silicon (Si), aluminum (Al), and nitrogen (N) atoms,
the second material comprises a silicon oxide, and
the third layer has a thickness of about 400 nm to about 500 nm.

20. The display device of claim 19, wherein:
a ratio of the thickness of the first layer to the thickness of the third layer is about 0.1 or less, and
a ratio of the thickness of the second layer to the thickness of the third layer is about 0.1 or less.
